(19) United States
(12) Patent Application Publication
(10) Pub. No.: US 2024/0224776 A1
(43) Pub. Date: Jul. 4, 2024

(54) FOLDABLE DISPLAY DEVICE

(71) Applicant: LG Display Co., Ltd., Seoul (KR)

(72) Inventors: SeokRak Chang, Seoul (KR); Jaewoo Lee, Gumi-si (KR)

(73) Assignee: LG Display Co., Ltd., Seoul (KR)

(21) Appl. No.: 18/517,256

(22) Filed: Nov. 22, 2023

(30) Foreign Application Priority Data
Dec. 30, 2022 (KR) 10-2022-0190740

(51) Int. Cl. H10K 77/10; H10K 59/80

(52) U.S. Cl. CPC H10K 77/111; H10K 59/8792; H10K 59/8793; H10K 2102/311

(57) ABSTRACT

A foldable display device includes a display panel including a display area and a non-display area configured to surround the display area, the display panel including a folding area defined in the display area and the non-display area, and non-folding areas disposed at two opposite sides in the folding area; a cover window disposed on the display panel and having a smaller size than the display panel; and a bonding layer disposed between the cover window and the display panel and configured to adjoin a bottom surface of the cover window, in which an end of the bonding layer in the folding area protrudes beyond an end of the bonding layer disposed in the non-folding areas in a direction of a folding axis. Therefore, even though bubbles are formed by repeated folding operations in the folding reliability test, the bubbles cannot be visible from the outside, thereby reducing the defect rate.

### CROSS-REFERENCE TO RELATED APPLICATION

This application claims the priority of Korean Patent Application No. 10-2022-0190740 filed on Dec. 30, 2022, which is hereby incorporated by reference in its entirety.

### BACKGROUND

### Field of the Disclosure

The present disclosure relates to a foldable display device, and more particularly, to a foldable display device with improved reliability.

### Description of the Background

Recently, display devices, which process and display a large amount of information, have been rapidly developed in accordance with the full-fledged entry into the information era. As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In particular, recently, flexible display devices, which are manufactured to be able to display images even when being bent or folded like paper, have attracted attention as next-generation display devices. The flexible display devices may be classified into an unbreakable display device having high durability and using a plastic thin-film transistor substrate instead of a glass substrate, a bendable display device capable of being bent without being broken, a rollable display device capable of being rolled circularly, and a foldable device capable of being folded. These flexible display devices may have spatial utilization and advantageous interior and design and be applied to various application fields.

### SUMMARY

The present disclosure is to provide a foldable display device having a structure capable of covering bubbles even though the bubbles are formed in a folding area.

In addition, the present disclosure is to provide a foldable display device with improved folding reliability.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings. The present disclosure is not limited to the above-mentioned and other features, which are not mentioned above, can be clearly understood by those skilled in the art from the following descriptions.

To achieve these and other advantages and in accordance with the present disclosure, as embodied and broadly described, a foldable display device includes a display panel including a display area and a non-display area configured to surround the display area. the display panel including a folding area defined in the display area and the non-display area, and non-folding areas disposed at two opposite sides in the folding area: a cover window disposed on the display panel and having a smaller size than the display panel: and a bonding layer disposed between the cover window and the display panel and configured to adjoin a bottom surface of the cover window, in which an end of the bonding layer in the folding area protrudes beyond an end of the bonding layer disposed in the non-folding areas in a direction of a folding direction. Therefore, even though bubbles are formed by repeated folding operations in the folding reliability test, the bubbles cannot be visible from the outside, thereby reducing the defect rate.

In another aspect of the present disclosure, a foldable display device includes a display panel including first and second non-folding areas and a folding area disposed between the first and second non-folding areas: a cover window disposed on the display panel and having a size smaller than the display panel: and a bonding layer disposed between the cover window and the display panel and including a first folding stress reducing part extended from side edges of a peripheral of the bonding layer in the folding area, wherein at least a portion of the first folding stress reducing part is flush with an edge of the cover window disposed in the folding area, and wherein the bonding layer has a size smaller than the cover window in the first and second non-folding areas.

In various aspects of the present disclosure, the foldable display device includes the first folding stress reducing part that is a rectangular shape or a partial circular shape.

In various aspects of the present disclosure, the foldable display device includes a protective film that is disposed on the cover window: and a black matrix layer that is disposed on a bottom surface of the protective film.

In various aspects of the present disclosure, the foldable display device includes the folding stress reducing part of the bonding layer overlapping the black matrix layer.

In various aspects of the present disclosure, the foldable display device includes the protective film having a first protective film disposed on the cover window: and a second protective film disposed between the first protective film and the cover window and including an anti-scattering layer.

In various aspects of the present disclosure, the foldable display device includes the second protective film having a size larger than the cover window.

In various aspects of the present disclosure, the foldable display device includes a second folding stress reducing part in a bottom plate disposed below the display panel, wherein the second folding stress reducing part is formed of a plurality of holes.

Other detailed matters of the exemplary aspects are included in the detailed description and the drawings.

According to the exemplary aspect of the present disclosure, the end of the bonding layer disposed below the cover window is coincident with the end of the cover window in the folding area of the display device, which makes it possible to inhibit bubbles formed in the folding area from being visually identified from the front surface.

According to the exemplary aspect of the present disclosure, the reliability of the display device may be improved.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a foldable display device according to an exemplary aspect of the present disclosure;

FIG. 2 is a plan view illustrating an arrangement of constituent elements of the foldable display device according to the exemplary aspect of the present disclosure;

FIG. 3 is a cross-sectional view taken along line III-III′ in FIG. 2; and

FIG. 4 is a plan view illustrating an arrangement of constituent elements of a foldable display device according to another exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, various aspects of the present disclosure will be described in detail with reference to accompanying drawings.

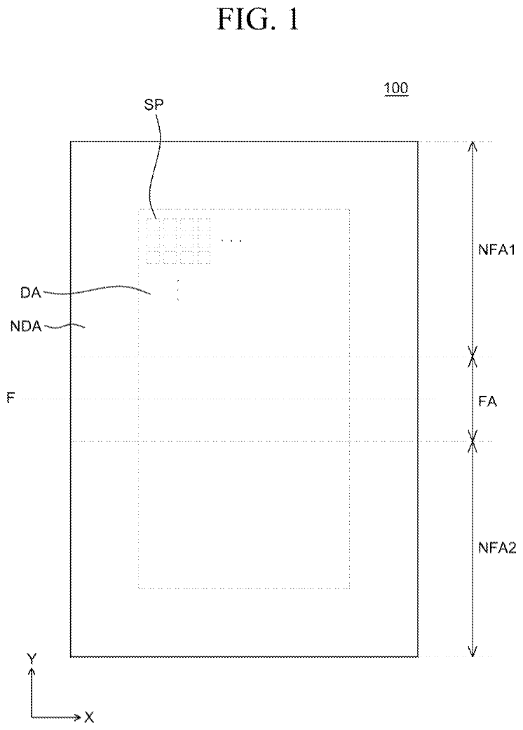

FIG. 1 is a plan view of a foldable display device according to an exemplary aspect of the present disclosure.

With reference to FIG. 1, a foldable display device 100 according to the exemplary aspect of the present disclosure may be a device for displaying images and include a display panel configured to display images. The display panel may include a display area DA and a non-display area NDA defined depending on whether the areas display images.

The display area DA may be an area in which a plurality of pixels is disposed to substantially display images. The plurality of pixels each including a light-emitting area for displaying images may be disposed in the display area DA. A thin-film transistor, a capacitor, and the like may be disposed in the display area DA to operate the pixels. One pixel may include a plurality of subpixels SP. The subpixels SP are minimum units that constitute the display area DA. Each of the subpixels SP may be configured to emit light within a particular wavelength band. For example, each of the subpixels SP may be configured to emit red light, green light, blue light, or white light.

The non-display area NDA may be disposed to surround the display area DA. The non-display area NDA is an area in which no image is displayed. Various lines, a drive IC, a printed circuit board, and the like may be disposed to operate the pixel and a drive circuit disposed in the display area DA. Although not shown in FIG. 1, for example, various ICs, such as a gate driver IC and a data driver IC, a VSS line, and the like may be disposed in the non-display area NDA.

The display panel of the foldable display device 100 according to the exemplary aspect of the present disclosure may include a folding area FA and non-folding areas NFAI and NFA2 disposed at two opposite sides (or both sides) of the folding area, which are defined depending on whether the areas are folded. For example, the foldable display device 100 may include the first non-folding area NFAI, the folding area FA, and the second non-folding area NFA2, which are sequentially disposed in a direction perpendicular (i.e., the Y-axis direction) to a folding axis F (i.e., the X-axis direction).

The folding area FA is an area that is folded when the foldable display device 100 is folded. The folding area FA may include a part of the display area DA and a part of the non-display area NDA. The folding area FA may be folded with a particular radius of curvature with respect to the direction perpendicular (the Y-axis direction) to the folding axis F (the X-axis direction)of the folding area. In case that the folding area FA is folded with respect to the direction perpendicular to the folding axis F, the folding area FA may define a part of a circle or ellipse. A radius of curvature of the folding area FA may be a radius corresponding to a part of a circle or ellipse defined by the folding area FA.

The first non-folding area NFA1 and the second non-folding area NFA2 may be areas that are not folded when the foldable display device 100 is folded. For example, each of the first non-folding area NFAl and the second non-folding area NFA2 may be an area that is kept in a flat state when the foldable display device 100 is folded. Each of the first non-folding area NFA1 and the second non-folding area NFA2 may also include a part of the display area DA and a part of the non-display area NDA. When the folding area FA is folded with respect to a folding direction, the first non-folding area NFA1 and the second non-folding area NFA2 may overlap with each other.

Hereinafter, a detailed configuration of the foldable display device 100 according to the exemplary aspect of the present disclosure will be described.

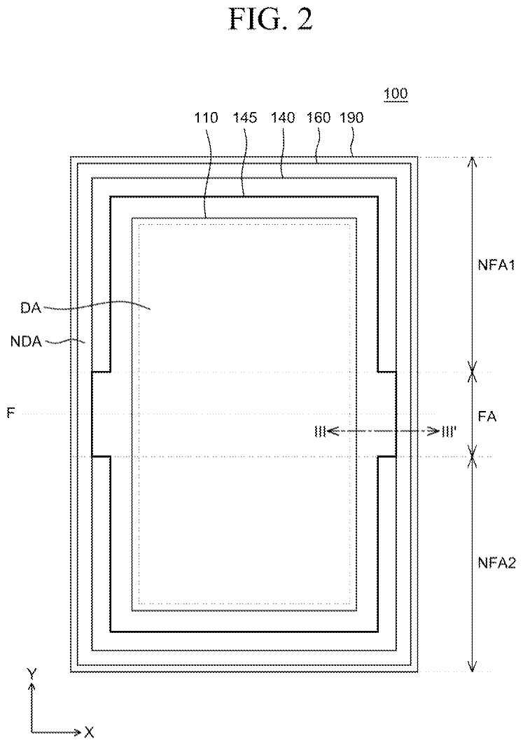

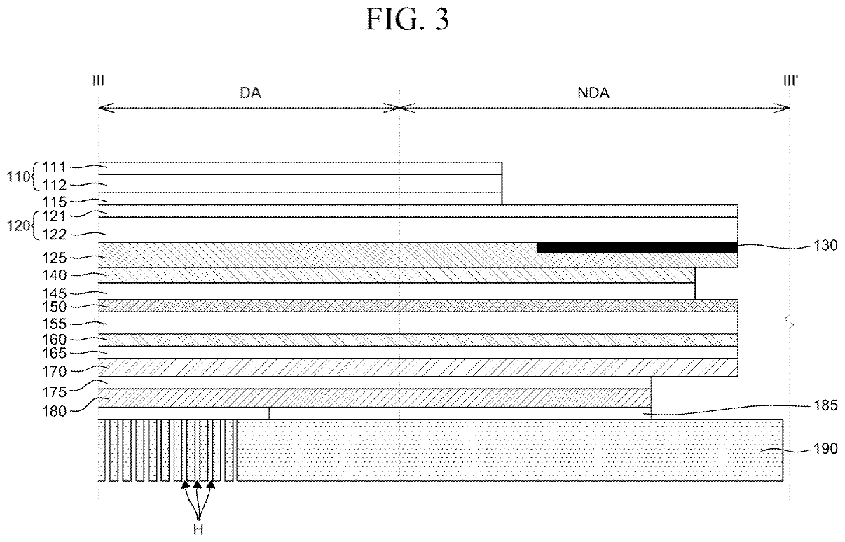

FIG. 2 is a plan view illustrating an arrangement of constituent elements of the foldable display device according to the exemplary aspect of the present disclosure. FIG. 3 is a cross-sectional view taken along line III-III′ in FIG. 2. For convenience of description, FIG. 2 illustrates only a first protective film 110, a third bonding layer 145, a cover window 140, a display panel 160, and a bottom plate 190 among various constituent elements of the foldable display device 100.

With reference to FIGS. 2 and 3, the foldable display device 100 according to the exemplary aspect of the present disclosure may include the first protective film 110, a first bonding layer 115, a second protective film 120, a second bonding layer 125, a black matrix layer 130, the cover window 140, the third bonding layer 145, a polarizing plate 150, a fourth bonding layer 155, the display panel 160, a fifth bonding layer 165, a base plate 170, a sixth bonding layer 175, a top plate 180, a seventh bonding layer 185, and the bottom plate 190.

The first protective film 110 may be disposed on the front surface of the foldable display device 100 and protect the cover window 140 and the display panel 160 from the external impact. The first protective film 110 may include a first hard coating layer 111 and a protective layer 112. The protective layer 112 may be coated with the first hard coating layer 111. The protective layer 112 may be made of flexible plastic to be folded. For example, the first protective film 110 may have a small thickness of 5 μm or less, which may effectively mitigate folding stress applied when the foldable display device 100 is folded. The first bonding layer 115 is disposed on the bottom surface of the first protective film 110.

The first bonding layer 115 may be disposed between the first protective film 110 and the second protective film 120 and attach the first protective film 110 and the second protective film 120. The first bonding layer 115 may be disposed to correspond to a length of the first protective film 110. For example, the first bonding layer 115 may be disposed to the extent of an arrangement length of the first protective film 110. The first bonding layer 115 may be made of a transparent material having bondability. The first bonding layer 115 may be a thermosetting or naturally curable bonding agent. For example, the first bonding layer 115 may be an optical clear adhesive (OCA), a pressure sensitive adhesive (PSA), or the like. However, the present disclosure is not limited thereto.

The second protective film 120 may be disposed below the first protective film 110 and protect the cover window 140 and the display panel 160. The second protective film 120 may have a size larger than the first protective film 110.

The second protective film 120 may include a second hard coating layer 121 and an anti-scattering layer 122. The second hard coating layer 121 may be disposed on the top surface of the anti-scattering layer 122 disposed below the second hard coating layer 121. The anti-scattering layer 122 may be coated with the second hard coating layer 121. The anti-scattering layer 122 may perform a buffering function and inhibit the first protective film 110 and the second protective film 120 from being damaged by the external impact. The anti-scattering layer 122 may inhibit debris from scattering even though the first protective film 110 and the second protective film 120 are damaged. The anti-scattering layer 122 may include polyurethane or silicon-based resin. The second bonding layer 125 and the black matrix layer 130 may be disposed on the bottom surface of the second protective film 120.

The second bonding layer 125 may be disposed between the second protective film 120 and the cover window 140 and attach the second protective film 120 and the cover window 140. The second bonding layer 125 may be made of a transparent material having bondability. The second bonding layer 125 may be a thermosetting or naturally curable bonding agent. For example, the second bonding layer 125 may be an optical clear adhesive (OCA), a pressure sensitive adhesive (PSA), or the like. However, the present disclosure is not limited thereto.

The black matrix (BM) layer 130 may be disposed on the bottom surface of the second protective film 120 while corresponding to the non-display area NDA. The black matrix layer 130 may include a material that can absorb light. For example, the black matrix layer 130 may include light absorption metal, carbon black, black resin, or the like. Therefore, constituent elements such as lines disposed in the non-display area NDA may not be visually identified from the outside. In addition, the black matrix layer 130 serves to suppress a leak of light from a side surface portion of the foldable display device 100.

The cover window 140 protects the display panel 160 from the external impact and scratches. The cover window 140 may be made of a transparent material that has properties in great impact resistance and scratch resistance. In addition, the cover window 140 protects the display panel 160 from the moisture or the like that penetrates from the outside.

The cover window 140 may be made of a flexible plastic-based material that is foldable to implement the thin and flexible foldable display device 100. For example, the cover window 140 may be a film made of polymer such as polyimide, polyamide-imide, polyethylene terephthalate, polymethyl methacrylate, polypropylene glycol, and polycarbonate.

The cover window 140 may be disposed to have a size smaller than the second protective film 120 in consideration of tolerance of attachment with the first protective film 110 and the second protective film 120. For example, an end of the cover window 140 may be positioned inward of an end of the second protective film 120. The third bonding layer 145 may be disposed on a bottom surface of the cover window 140.

The third bonding layer 145 may be disposed between the cover window 140 and the polarizing plate 150 and attach the cover window 140 and the polarizing plate 150. The third bonding layer 135 may be made of a transparent material having bondability. The third bonding layer 135 may be a thermosetting or naturally curable bonding agent. For example. the third bonding layer 135 may be an optical clear adhesive (OCA) or the like. However, the present disclosure is not limited thereto.

The third bonding layer 145 may have various lengths that are different in the folding area FA and the non-folding area NFA. For example, as illustrated in FIG. 2, the third bonding layer 145 may be further expanded in the folding area FA than in the non-folding area NFA. For example, the end of the third bonding layer 145 in the folding area FA may be disposed to protrude beyond the end of the third bonding layer 145 in the non-folding area NFA in a folding direction.

The third bonding layer 145 may be disposed to be further expanded in the folding area FA than in the non-folding area NFA. The third bonding layer 145 may have a longer length in the folding area FA than in the non-folding area NFA. For example, as illustrated in FIG. 2, the portion of the end of the third bonding layer 145 disposed in the folding area FA may be coincident (or flush) with the end of the cover window 140. The remaining portion of the end of the third bonding layer 145 in the non-folding area NFA may be positioned inward of the end of the cover window 140.

The polarizing plate 150 may be provided to reinforce optical characteristics of the display panel 160. The polarizing plate 150 may be a polarizing film, a polarizing layer, or the like. However, the present disclosure is not limited thereto. The polarizing plate 150 may selectively transmit light and reduce reflection of external light entering the display panel 160. For example, various metallic materials applied to semiconductor elements, lines, light-emitting elements, and the like are disposed on the display panel 160, and external light having entered the display panel 160 may be reflected by the metallic material on the display panel 160. The reflection of the external light may degrade visibility of the display panel 160. Therefore, the polarizing plate 150 may be disposed to improve outdoor visibility of the foldable display device 100 made by the reflection of the external light.

The polarizing plate 150 may have a size larger than the cover window 140. For example, the end of the polarizing plate 150 may be positioned outward of the end of the cover window 140. The polarizing plate 150 may be excluded in accordance with the implementation of the foldable display device 100. The fourth bonding layer 155 is disposed on the bottom surface of the polarizing plate 150.

The fourth bonding layer 155 may be disposed between the polarizing plate 150 and the display panel 160 and attach the polarizing plate 150 and the display panel 160. The fourth bonding layer 155 may be disposed to correspond to a size of the polarizing plate 150. For example, the end of the fourth bonding layer 155 may be coincident (or flush) with the end of the polarizing plate 150.

The fourth bonding layer 155 may be made of a transparent material having bondability. The fourth bonding layer 155 may be a thermosetting or naturally curable bonding agent. For example, the fourth bonding layer 155 may be an optical clear adhesive (OCA), a pressure sensitive adhesive (PSA), or the like. However, the present disclosure is not limited thereto.

The display panel 160 is a panel for implementing images. Light-emitting elements for implementing images, circuit parts for operating the light-emitting elements, and the like may be disposed on the display panel 160. For example, in case that the display panel 160 is an organic light-emitting display panel, the light-emitting element may be an organic light-emitting element. The circuit part may include various thin-film transistors, capacitors, lines, drive ICs, and the like for operating the light-emitting elements. For example, the circuit parts may include various components such as drive thin-film transistors, switching thin-film transistors, storage capacitors, gate lines, data lines, gate driver ICs, and data drivers IC. However, the present disclosure is not limited thereto.

The display panel 160 is made by forming the drive thin-film transistors and the light-emitting elements on a flexible substrate and sealing the flexible substrate with a sealing part. The display panel 160 may include a flexible substrate having a very small thickness for implementing flexibility, and a light-emitting element disposed on the flexible substrate.

The flexible substrate may be made of an insulating material having flexibility. For example, the flexible substrate may be an insulating plastic substrate made of a material including one of polyimide, polyether sulfone, polyethylene terephthalate, and polycarbonate. The plastic substrate has relatively low barrier characteristics against the moisture or oxygen. Therefore, the plastic substrate may have a structure in which a plastic film and an inorganic film are stacked to supplement the barrier characteristics. For example, the flexible substrate may include a multilayer structure in which a first plastic film, an inorganic film, and a second plastic film are sequentially stacked. However, the present disclosure is not limited thereto.

The drive thin-film transistor for operating the light-emitting element may be disposed on the flexible substrate. The drive thin-film transistors may be respectively disposed in a plurality of pixel areas. For example, the drive thin-film transistor may include a gate electrode, an active layer, a source electrode, and a drain electrode. For example, the drive thin-film transistor may further include a gate insulation layer for insulating the gate electrode and the active layer. The drive thin-film transistor may further include an interlayer insulation layer for insulating the gate electrode, the source electrode, and the drain electrode. A planarization layer may be disposed on the drive thin-film transistor to planarize a top surface. The light-emitting element may be disposed on the planarization layer, and the light-emitting element may be an organic light-emitting element. The organic light-emitting element emits light as positive holes injected from an anode are coupled to electrons injected from a cathode in an organic light-emitting layer. Images may be displayed by using the light emitted as described above.

The flexible substrate has excellent folding characteristics. However, because the flexible substrate has a small thickness and has rigidity lower than a glass substrate or a metal substrate, the flexible substrate may hardly maintain a constant shape when being folded, and the flexible substrate may sag. The base plate 170, the top plate 180, and the bottom plate 190 may be disposed below the display panel 160 to support the flexible substrate and improve impact resistance. The fifth bonding layer 165 may be disposed on the bottom surface of the display panel 160.

The fifth bonding layer 165 may be disposed between the display panel 160 and the base plate 170 and attach the display panel 160 and the base plate 170. The fifth bonding layer 165 may be made of a transparent material having bondability. The fifth bonding layer 165 may be a thermosetting or naturally curable bonding agent. For example, the fifth bonding layer 165 may be an optical clear adhesive (OCA), a pressure sensitive adhesive (PSA), or the like. However, the present disclosure is not limited thereto.

The base plate 170 may be disposed on the bottom surface of the display panel 160. The base plate 170 may be disposed between the display panel 160 and the top plate 180 and suppress a situation in which a display screen is transferred or distorted by a plurality of hole patterns H provided in the bottom plate 190. For example, the base plate 170 may be made of polymer such as polyimide (PI), polymethyl methacrylate (PDMA), polycarbonate (PC), polyvinyl alcohol (PVA), acrylonitrile-butadiene-styrene (ABS), polyethylene terephthalate (PET), silicone, and polyurethane (PU). The base plate 170 may be attached to the top plate 180 by the sixth bonding layer 175.

The sixth bonding layer 175 may be disposed between the base plate 170 and the top plate 180 and attach the base plate 170 and the top plate 180. The sixth bonding layer 175 may be made of a material having bondability. The sixth bonding layer 175 may be a thermosetting or naturally curable bonding agent. For example, the sixth bonding layer 175 may be an optical clear adhesive (OCA), a pressure sensitive adhesive (PSA), or the like. However, the present disclosure is not limited thereto.

The top plate 180 may be disposed below the base plate 170 and reinforce rigidity of the display panel 160. The top plate 180 may serve to inhibit the plurality of hole patterns H, which is formed in the bottom plate 190 disposed below the top plate 180, from being visually identified through the display panel 160.

The top plate 180 may be made of amorphous metal. The amorphous metal means metal solidified into a state in which atoms are arranged in an amorphous manner, like glass or liquid. The amorphous metal is created when raw metal materials are supercooled and growth of crystals is disrupted. In general, the amorphous metal is better in corrosion resistance and elastic characteristics than crystalline metal having a regular arrangement of atoms. For example, the top plate 180 may include one amorphous metal including one of nickel, iron, cobalt, palladium, silicon, magnesium, zirconium, titanium, calcium, copper, platinum, gold, and combinations thereof. The top plate 180 may be attached to the bottom plate 190 by the seventh bonding layer 185.

The seventh bonding layer 185 may be disposed between the top plate 180 and the bottom plate 190 and attach the top plate 180 and the bottom plate 190. Because the plurality of hole patterns H is formed in the bottom plate 190 to implement elastic deformation made by folding, the seventh bonding layer 185 may be disposed so as not to overlap the plurality of hole patterns H of the bottom plate 190. The seventh bonding layer 185 may be made of a material having bondability. The seventh bonding layer 185 may be a thermosetting or naturally curable bonding agent. For example, the seventh bonding layer 185 may be an optical clear adhesive (OCA), a pressure sensitive adhesive (PSA), or the like. However, the present disclosure is not limited thereto.

The bottom plate 190 may be disposed below the top plate 180. The bottom plate 190 may be made of a metallic material such as stainless steel (SUS), stainless steel (SUS) containing metal such as nickel (Ni), iron (Fe), aluminum (Al), and magnesium (Mg). The bottom plate 190 may be made of stainless steel (SUS). However, the present disclosure is not limited thereto. For example, because stainless steel (SUS) has high restoring force and rigidity, the bottom plate 190 may maintain high rigidity even though a thickness of the bottom plate 190 decreases. For example, the bottom plate 190 may be made of polymer such as polyimide (PI), polymethyl methacrylate (PDMA), polycarbonate (PC), polyvinyl alcohol (PVA), acry lonitrile-butadiene-styrene (ABS), polyethylene terephthalate (PET), silicone, and polyurethane (PU). The bottom plate 190 may support the display panel 160 and reduce a radius of curvature of the folding area FA by decreasing an overall thickness of the foldable display device 100.

The plurality of hole patterns H may be disposed in the bottom plate 190 to reduce stress occurring when the foldable display device 100 is folded. The plurality of hole patterns H may be disposed to correspond to the folding area FA of the foldable display device 100. FIG. 3 illustrates that the plurality of hole patterns H corresponds to the display area DA. However, the present disclosure is not limited thereto. The plurality of hole patterns H may be formed to correspond to the folding area FA and formed in a part of the display area DA in the folding area FA and a part or the entirety of the display area DA and the non-display area NDA.

In a general foldable display device, in consideration of tolerance of attachment during a process of attaching a first protective film, a second protective film, a cover window, a polarizing plate, and a display panel, the cover window having a smaller size than the second protective film is attached, and the third bonding layer is disposed so that the third bonding layer attached to a bottom surface of the cover window has a length shorter than a length of the cover window.

Since the third bonding layer 145 is disposed to have a length shorter than a length of the cover window 140, fine bubbles may be formed in the third bonding layer due to folding stress occurring when the folding operation for a folding test for a foldable display device is repeatedly performed. Further, sizes of the fine bubbles may be increased by the repeated folding operations, and the fine bubbles may emerge from a black matrix layer 130, which causes a problem in that the bubbles may be visually identified.

Accordingly, the present disclosure is to provide the display device that can reduce the visibility of bubbles in the bonding layer that occur in the folding area of the display device, so that the display device in the present disclosure that may improve reliability by reducing the visibility of bubbles in the bonding layer that occur in the folding area. This will be described below:

In the foldable display device 100 according to the exemplary aspect of the present disclosure, the third bonding layer 145 is disposed to be coincident (or flush) with the end of the cover window 140 only in the folding area FA. In the non-folding area NFA, the third bonding layer 145 may be disposed such that the end of the third bonding layer 145 is positioned inward of the cover window 140 in consideration of tolerance of attachment. Therefore, the foldable display device 100 according to the exemplary aspect of the present disclosure may improve folding reliability by inhibiting the bubbles formed in the bonding layer in the folding area FA from being visually identified.

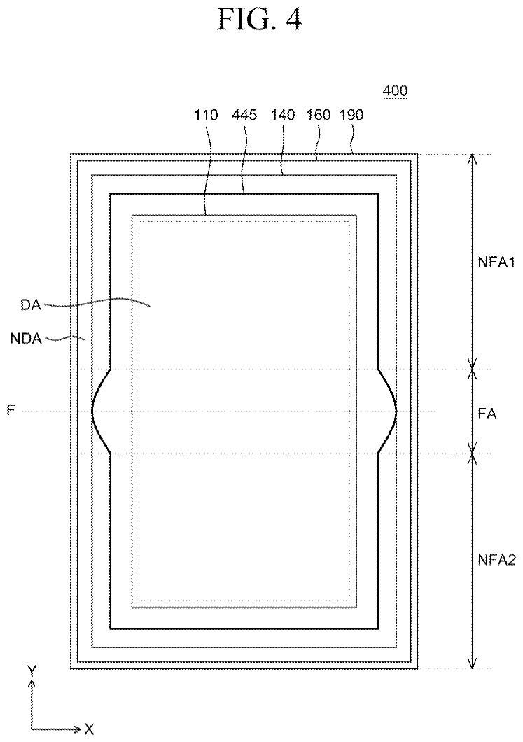

FIG. 4 is a plan view illustrating an arrangement of constituent elements of a foldable display device according to another exemplary aspect of the present disclosure. To describe characteristics of another exemplary aspect of the present disclosure, FIG. 4 illustrates only a protective film 110, the cover window 140, a bonding layer 445, the display panel 160, and the bottom plate 190. A foldable display device 400 in FIG. 4 differs from the foldable display device 100 in FIG. 2 in terms of the bonding layer 445 configured to attach the cover window 140 and the polarizing plate. The foldable display device 400 is substantially similar in other configurations to the foldable display device 100, and a repeated description will be omitted.

With reference to FIG. 4, the foldable display device 400 according to another exemplary aspect of the present disclosure may include the first protective film 110, the cover window 140 disposed below the first protective film 110, the bonding layer 445 disposed on the bottom surface of the cover window 140, the display panel 160 disposed below the cover window 140, and the bottom plate 190 disposed below the display panel 160.

The bonding layer 445 may be disposed on the bottom surface of the cover window 140 and attach the cover window 140 and the polarizing plate 150. The bonding layer 445 may be made of a transparent material having bondability. The bonding layer 445 may be a thermosetting or naturally curable bonding agent. For example, the bonding layer 445 may be an optical clear adhesive (OCA), a pressure sensitive adhesive (PSA), or the like. However, the present disclosure is not limited thereto.

The bonding layer 445 may be disposed to have various lengths that are different in the folding area FA and the non-folding area NFA. For example, the bonding layer 445 may be disposed to be further expanded in the folding area FA than in the non-folding area NFA. The bonding layer 445 may have a longer length in the folding area FA than in the non-folding area NFA.

The bonding layer 445 may be disposed to be further expanded in the folding area FA than in the non-folding area NFA. The bonding layer 445 may be disposed to have a length that gradually decreases as the distance from the non-folding area NFA decreases with respect to the folding axis F. For example, because highest folding stress is applied to the bonding layer 445 disposed on the folding axis F in the folding area FA, the end of the bonding layer 445 may be disposed to be coincident with the end of the cover window 140, and the end of the bonding layer 445 is positioned to be gradually inward further than the end of the cover window 140 as the distance from the non-folding area NFA decreases. For example, the bonding layer 445 disposed in the area coincident with the folding axis F in the folding area FA may have the longest length. The bonding layer 445 disposed in the folding area FA closest to the non-folding area NFA may have the shortest length in the folding area FA.

In the foldable display device 400 according to another exemplary aspect of the present disclosure, the bonding layer 445 disposed on the bottom surface of the cover window 140 may be disposed to have different lengths in the folding area FA and the non-folding area NFA. In the folding area FA, the bonding layer 445 may be disposed on the folding axis F to be coincident with the end of the cover window 140. As the distance from the non-folding area NFA decreases, the end of the bonding layer 445 is positioned to be gradually close to the inside that is distant from the end of the cover window 140.

The exemplary aspects of the present disclosure may also be described as follows:

According to an aspect of the present disclosure, a foldable display device includes: a display panel including a display area and a non-display area configured to surround the display area, the display panel including a folding area defined in the display area and the non-display area, and non-folding areas disposed at two opposite sides in the folding area: a cover window disposed on the display panel and having a smaller size than the display panel: and a bonding layer disposed between the cover window and the display panel and configured to adjoin a bottom surface of the cover window, in which an end of the bonding layer in the folding area protrudes beyond an end of the bonding layer disposed in the non-folding areas in a direction of a folding direction. Therefore, even though bubbles are formed by repeated folding operations in the folding reliability test, the bubbles cannot be visible from the outside, thereby reducing the defect rate.

The end of the bonding layer in the folding area may be coincident with an end of the cover window, and the end of the bonding layer in the non-folding areas may be positioned to be closer to the inside of the cover window than the end of the cover window.

An area in which the end of the bonding layer in the folding area may be coincident with the end of the cover window may be an area corresponding to a folding axis.

An end of the bonding layer, which is disposed in the folding area to be closest to the non-folding areas, may be disposed to be closer to the outside of the cover window than an end of the bonding layer disposed in the non-folding areas.

The end of the bonding layer, which is disposed in the folding area to be closest to the non-folding areas, may be disposed to be closer to the inside of the cover window than an end of the bonding layer disposed in the area corresponding to the folding axis.

An end of a bonding layer between a bonding layer, which is disposed in the folding area to be closest to the non-folding areas, and a bonding layer, which is disposed to correspond to the folding axis, may be disposed to be gradually close to the inside of the cover window between the end of the bonding layer disposed to be closest to the non-folding areas and the end of the bonding layer disposed to correspond to the folding axis.

The bonding layer may be an optical clear adhesive (OCA).

The foldable display device may further comprise a protective film disposed on the cover window: and a black matrix layer disposed on a bottom surface of the protective film to correspond to the non-display area.

An end of the bonding layer in the folding area may be disposed to overlap the black matrix layer.

The protective film may comprise a first protective film disposed on the cover window and configured to define a front surface: and a second protective film disposed between the first protective film and the cover window and including an anti-scattering layer.

The second protective film may have a larger size than the cover window.

The foldable display device may further comprise a bottom plate disposed below the display panel to support the display panel.

A plurality of hole patterns may be disposed in the bottom plate to reduce folding stress.

The foldable display device may further comprise a polarizing plate disposed between the bonding layer and the display panel.

The bonding layer may bond the cover window and the polarizing plate.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A foldable display device comprising:
a display panel including a display area and a non-display area configured to surround the display area, the display panel including a folding area defined in the display area and the non-display area and non-folding areas disposed at two opposite sides in the folding area:
a cover window disposed on the display panel and having a size smaller than the display panel: and
a bonding layer disposed between the cover window and the display panel and configured to adjoin a bottom surface of the cover window,
wherein an end of the bonding layer in the folding area protrudes beyond an end of the bonding layer disposed in the non-folding areas in a direction of a folding direction.

2. The foldable display device of claim 1, wherein the end of the bonding layer in the folding area is coincident with an end of the cover window, and the end of the bonding layer in the non-folding areas is positioned to be closer to inside the cover window than the end of the cover window.

3. The foldable display device of claim 2, wherein an area in which the end of the bonding layer in the folding area is coincident with the end of the cover window is an area corresponding to a folding axis.

4. The foldable display device of claim 3, wherein an end of the bonding layer, which is disposed in the folding area so as to be closest to the non-folding areas, is disposed to be closer to the outside of the cover window than an end of the bonding layer disposed in the non-folding areas, and
wherein the end of the bonding layer disposed in the folding area is disposed to be closest to the non-folding areas and is disposed to be closer to the inside of the cover window than an end of the bonding layer disposed in the area corresponding to the folding axis.

5. The foldable display device of claim 4, wherein an end of a bonding layer between a bonding layer, which is disposed in the folding area so as to be closest to the non-folding areas, and a bonding layer, which is disposed to correspond to the folding axis, is disposed to be gradually close to the inside of the cover window between the end of the bonding layer disposed to be closest to the non-folding areas and the end of the bonding layer disposed to correspond to the folding axis.

6. The foldable display device of claim 5, wherein the bonding layer includes an optical clear adhesive (OCA).

7. The foldable display device of claim 1, further comprising:
a protective film disposed on the cover window; and
a black matrix layer disposed on a bottom surface of the protective film to correspond to the non-display area.

8. The foldable display device of claim 7, wherein the end of the bonding layer in the folding area is disposed to overlap the black matrix layer.

9. The foldable display device of claim 7, wherein the protective film comprises:
a first protective film disposed on the cover window and configured to define a front surface; and
a second protective film disposed between the first protective film and the cover window and including an anti-scattering layer.

10. The foldable display device of claim 9, wherein the second protective film has a size larger than the cover window.

11. The foldable display device of claim 1, further comprising a bottom plate disposed below the display panel to support the display panel,
wherein the bottom plate includes a plurality of hole patterns to reduce folding stress.

12. The foldable display device of claim 1, further comprising a polarizing plate disposed between the bonding layer and the display panel,
wherein the bonding layer bonds the cover window and the polarizing plate.

13. A foldable display device comprising:
a display panel including a folding area associated with a folding axis and non-folding areas at two sides of the folding area:
a cover window disposed on the display panel: and
a bonding layer disposed between the cover window and the display panel and adjoining a bottom surface of the cover window,
wherein, in a direction of the folding axis, a length of the bonding layer in the folding area is greater than a length of the bonding layer in the non-folding areas.

14. A foldable display device comprising:
a display panel including first and second non-folding areas and a folding area disposed between the first and second non-folding areas:
a cover window disposed on the display panel and having a size smaller than the display panel: and
a bonding layer disposed between the cover window and the display panel and including a first folding stress reducing part extended from side edges of a peripheral of the bonding layer in the folding area,
wherein at least a portion of the first folding stress reducing part is flush with an edge of the cover window disposed in the folding area, and
wherein the bonding layer has a size smaller than the cover window in the first and second non-folding areas.

15. The foldable display device of claim 14, wherein the first folding stress reducing part is a rectangular shape or a partial circular shape.

16. The foldable display device of claim 14, further comprising:
a protective film disposed on the cover window; and
a black matrix layer disposed on a bottom surface of the protective film.

17. The foldable display device of claim 16, wherein the folding stress reducing part of the bonding layer overlaps the black matrix layer.

18. The foldable display device of claim 17, wherein the protective film comprises:
a first protective film disposed on the cover window; and
a second protective film disposed between the first protective film and the cover window and including an anti-scattering layer.

19. The foldable display device of claim 18, wherein the second protective film has a size larger than the cover window.

20. The foldable display device of claim 14, further comprising a second folding stress reducing part in a bottom plate disposed below the display panel,
wherein the a second folding stress reducing part is formed of a plurality of holes.
